(19) United States
(12) Patent Application Publication
(10) Pub. No.: US 2026/0181996 A1
(43) Pub. Date: Jun. 25, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chu-Fu Lin, Kaohsiung City (TW); Chuan-Lan Lin, Chiayi City (TW); Min-Shiang Hsu, Kaohsiung City (TW); Chien-Ting Lin, Tainan City (TW); Yu-Ping Wang, Hsinchu City (TW)

(73) Assignee: UNITED MICROELECTRONICS CORP., Hsin-Chu City (TW)

(21) Appl. No.: 19/048,948

(22) Filed: Feb. 9, 2025

(30) Foreign Application Priority Data
Dec. 24, 2024 (TW) 113150377

(51) Int. Cl. H10D 84/01; H01L 23/00; H10D 84/40

(52) U.S. Cl. CPC H10D 84/0107; H10D 84/40; H10W 72/012; H10W 72/242

(57) ABSTRACT

A method for fabricating a semiconductor device includes the steps of first providing a substrate having through-silicon vias (TSVs) therein, forming an inorganic layer on the substrate, forming an organic layer on the inorganic layer, and then bonding dies having different functionalities on the organic layer. Preferably, the dies include a radio-frequency integrated circuit (RFIC) die, a power amplifier (PA) die, and/or a high electron mobility transistor (HEMT) die.

### BACKGROUND OF THE INVENTION

### 1. Field of the Invention

The invention relates to a method of fabricating semiconductor device, and more particularly, to a method of integrating dies having different functionalities onto a silicon wafer for forming a package structure.

### 2. Description of the Prior Art

As technology evolves, wireless communication is an important part of human life. Various electronic devices, such as smart phones, smart wearable devices, tablets, etc., utilize wireless radio frequency (RF) systems to transmit and receive wireless signals. A low noise amplifier (LNA) and a power amplifier (PA) are necessary amplifying circuits in the wireless RF system. In order to achieve better performance (e.g., linearity), the amplifying circuit requires an appropriate bias point. A common way is to electrically connect a biasing module to the amplifying circuit, so as to utilize the biasing module for providing a bias point for the amplifying circuit.

In addition, the semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (PoP) devices and so on.

Typically, current RF devices often have drawbacks including higher resistance and large parasitic capacitance that ultimately affect overall performance of the devices. Hence, how to integrate RF devices with other logic devices for forming a package structure under reliable environment has become an important task in this field.

### SUMMARY OF THE INVENTION

According to an embodiment of the present invention, a method for fabricating a semiconductor device includes the steps of first providing a substrate having through-silicon vias (TSVs) therein, forming an inorganic layer on the substrate, forming an organic layer on the inorganic layer, and then bonding dies having different functionalities on the organic layer. Preferably, the dies include a radio-frequency integrated circuit (RFIC) die, a power amplifier (PA) die, and/or a high electron mobility transistor (HEMT) die.

According to another aspect of the present invention, a semiconductor device includes a substrate having through-silicon vias (TSVs) therein, an inorganic layer on the substrate, an organic layer on the inorganic layer, and dies having different functionalities bonded on the organic layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a method for fabricating a semiconductor device according to an embodiment of the present invention.

FIGS. 2-13 illustrate a method for fabricating the semiconductor device shown in FIG. 1 according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,”“an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,”“upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

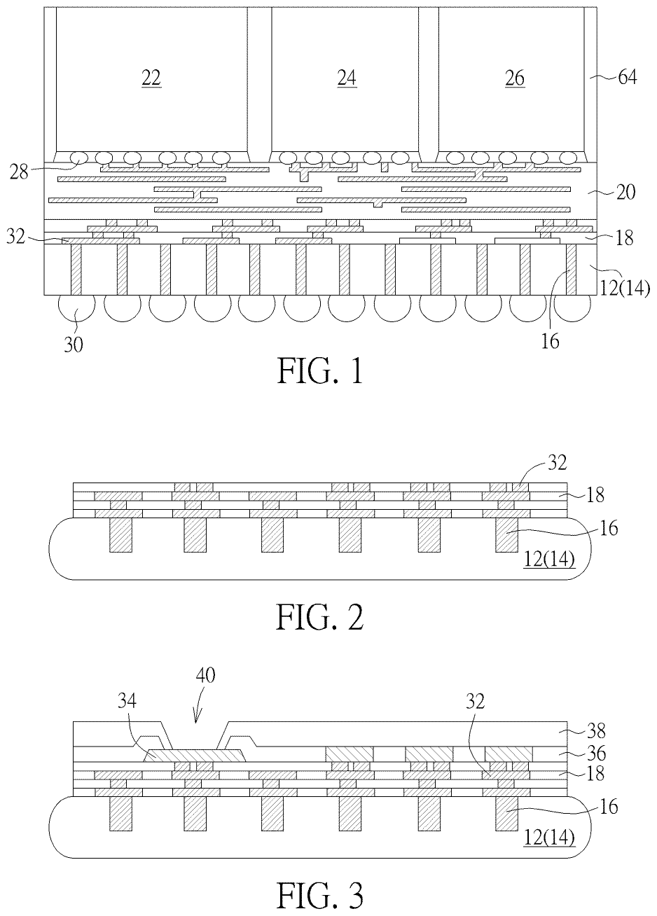

Referring to FIG. 1, FIG. 1 illustrates a method for fabricating a semiconductor device according to an embodiment of the present invention. As shown in FIG. 1, a wafer 12 made of semiconductor material is provided, in which the wafer 12 includes a substrate made of semiconductor materials as the substrate could also be made of semiconductor substrate material including but not limited to for example silicon substrate, epitaxial silicon substrate, silicon carbide substrate or even a silicon-on-insulator (SOI) substrate, which are all within the scope of the present invention. In this embodiment, the wafer 12 in the later process could be used for fabricating elements including MV devices, HV devices, pixel circuits, LV devices for LV driving circuits, and/or graphics process unit (GPU).

Next, a front end of line (FEOL) and a back end of line (BEOL) fabrication processes could be conducted on the wafer 12. In this embodiment, the FEOL process could include the process of forming metal-oxide semiconductor (MOS) transistors, oxide semiconductor field effect transistors (OS FETs), fin field effect transistor (FinFETs), or other active devices and/or passive devices. BEOL process on the other hand could include forming metal interconnect structures such as metal inter-metal dielectric (IMD) layers 18 and metal interconnections 20 on the aforementioned active devices and/or passive devices.

If a MOS transistor were to be fabricated, the FEOL process could include the steps of forming a gate structure on the substrate 14, forming a spacer (not shown) adjacent to sidewalls of the gate structure, and forming a source/drain region in the substrate 14 adjacent to two sides of the spacer, in which the gate structure could include polysilicon or metal, the spacer could include dielectric material such as silicon oxide or silicon nitride, and the source/drain region could include p-type dopants or n-type dopants depending on the conductive type of the transistor being fabricated.

Next, an interlayer dielectric (ILD) layer could be formed on the substrate 14 to cover the MOS transistor or other active devices, and then a contact plug formation and metal interconnect process from BEOL process could be conducted to form a plurality of contact plugs in the ILD layer for connecting the source/drain region and the gate structure, an inter-metal dielectric (IMD) layer disposed on the ILD layer, and metal interconnections in the IMD layer for connecting the contact plugs, in which the topmost metal interconnection on front side of the first wafer could be used as connecting junctions such as direct bond interconnects (DBIs) for connecting to DBIs of another wafer in the later process. In this embodiment, the ILD layer and the IMD layer could include oxides including but not limited to for example tetraethyl orthosilicate (TEOS) and the contact plugs and the metal interconnections or DBIs could include Al, Cr, Cu, Ta, Mo, W, or combination thereof. It should be noted that through-silicon vias (TSVs) 16 are formed in and through the substrate 14 of the wafer 12 to connect to the active devices and/or passive devices on the substrate 14.

Next, an inorganic layer 18 is formed on the substrate 14, an organic layer 20 is formed on the inorganic layer 18, a plurality of dies 22, 24, 26 having different functionalities and diced through a dicing process are bonded onto the organic layer 20 through micro bumps 28, and then a plurality of solder balls 30 are connected to the TSVs 16 on the bottom of the substrate 14. In this embodiment, the die 22 disposed on the organic layer 20 could include radio frequency integrated circuit (RFIC) dies, the die 24 could include power amplifier (PA) dies, and the die 26 could include high electron mobility transistors (HEMTs) commonly fabricated from III-V semiconductors such as gallium nitride (GaN). Preferably, the pitch of the TSVs 16 is between 15-25 microns or most preferably 20 microns, the line/space of the metal interconnections in the inorganic layer 18 is between 0.2-0.6 microns or most preferably 0.4 microns, the line/space of the metal interconnections in the organic layer 20 is between 0.8-1.2 microns or most preferably 1.0 micron, and the pitch of the micro bumps 28 is between 25-40 microns.

Referring to FIGS. 2-13, FIGS. 2-13 illustrate details for fabricating the semiconductor device shown in FIG. 1 according to an embodiment of the present invention. As shown in FIG. 2, a silicon wafer or substrate 14 having elements fabricated through the aforementioned BEOL processes and TSVs 16 therein is provided and then one or more inorganic layers 18 made of inorganic material is formed on the TSVs 16. According to an embodiment of the present invention, the inorganic layer 18 is the IMD layer formed in the aforementioned BEOL process, in which the inorganic layer 18 could include dielectric materials such as silicon oxide (SiO₂), silicon nitride (SiN), a low-k (LK) dielectric layer, or an ultra low-k (ULK) dielectric layer including but not limited to for example porous material such as silicon oxycarbide (SiOC) or SiOCH.

Next, metal interconnections 32 are formed in the inorganic layer 18, in which the metal interconnections 32 could include Al, Cr, Cu, Ta, Mo, W, or combination thereof. Specifically, the metal interconnections 32 could include trench conductors and/or via conductors and each of the metal interconnections 32 could be fabricated through single damascene or dual damascene processes in the inorganic layer 18 and connected to each other. For instance, each of the metal interconnections 32 could further include a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity.

Next, as shown in FIG. 3, one or more bonding pad 34 could be formed to connect the metal interconnections 32, a passivation layer 36 is formed to cover the inorganic layer 18 and the metal interconnections 32, and then a photo-etching process is conducted to remove part of the passivation layer 36 for forming an opening exposing the bonding pad 34. In this embodiment, the bonding pad 34 could be viewed as part of the metal interconnections 32, the bonding pad 34 could include aluminum or copper, and the passivation layer 36 could include silicon oxide or silicon nitride.

Next, a first organic layer 38 is formed on the passivation layer 36 and then another photo-etching process is conducted by using a patterned mask (not shown) as mask to remove part of the first organic layer 38 for forming an opening 40 exposing part of the bonding pad 34 underneath. In this embodiment, the first organic layer 38 is preferably made of an organic dielectric layer made from organic material such as polyimide (PI), polybenzoxazole (PBO), or benzocyclobutene (BCB).

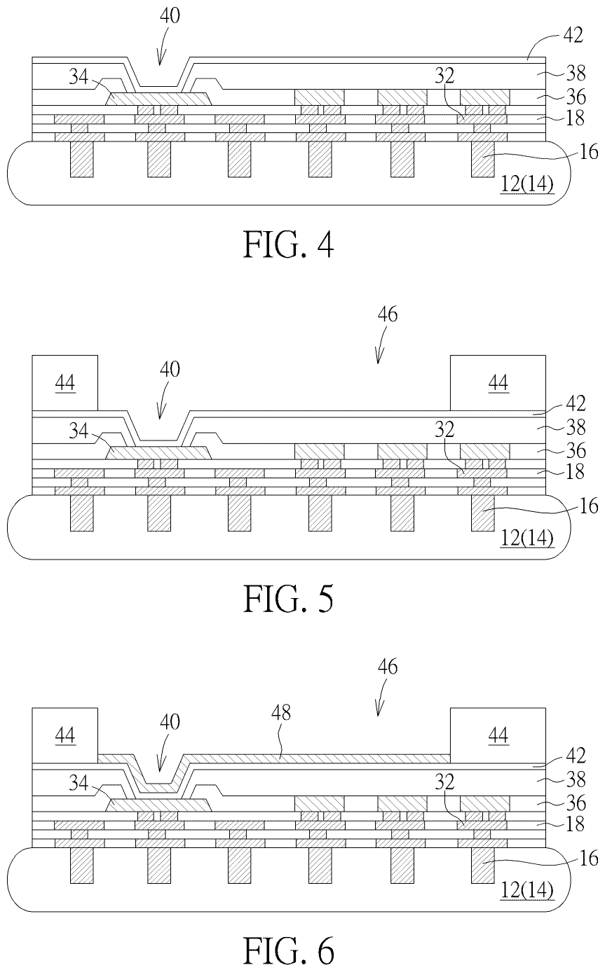

Next, as shown in FIG. 4, processes including sputtering, deposition, and etching could be carried out to form a first under bump metallurgy (UBM) layer 42 made of multiple UBM layers on the first organic layer 38 and part of the bonding pad 34 in the opening 40. In this embodiment, the first UBM layer 42 could further include an adhesion layer, a barrier layer, and a wetting layer. Preferably, the adhesion layer functions to provide adequate adhesiveness for the bonding pad 34 and the passivation layer 36, in which the adhesion layer could include aluminum, titanium, chromium, titanium tungsten, or combination thereof. The barrier layer functions to prevent a diffusion phenomenon from occurring between the solder balls and the bonding pad 34, in which the barrier layer could include nickel or nickel vanadium. The wetting layer functions to provide adequate adhesiveness between the first UBM layer 42 and solder balls formed afterwards, in which the wetting layer could include copper, molybdenum, platinum, or combination thereof.

Next, as shown in FIG. 5, a patterned mask 44 such as patterned resist is formed on the first UBM layer 42, in which the patterned mask 44 includes an opening 46 exposing the surface of first UBM layer 42 directly on top of the bonding pad 34 and the first UBM layer 42 adjacent to two sides of the bonding pad 34.

Next, as shown in FIG. 6, an electroplating process is conducted to form a patterned metal layer 48 in the opening 46 and on the surface of the first UBM layer 42. According to an embodiment of the present invention, the patterned metal layer 48 could be viewed as part of the first UBM layer 42 and the patterned metal layer 48 is made of copper (Cu), but not limited thereto.

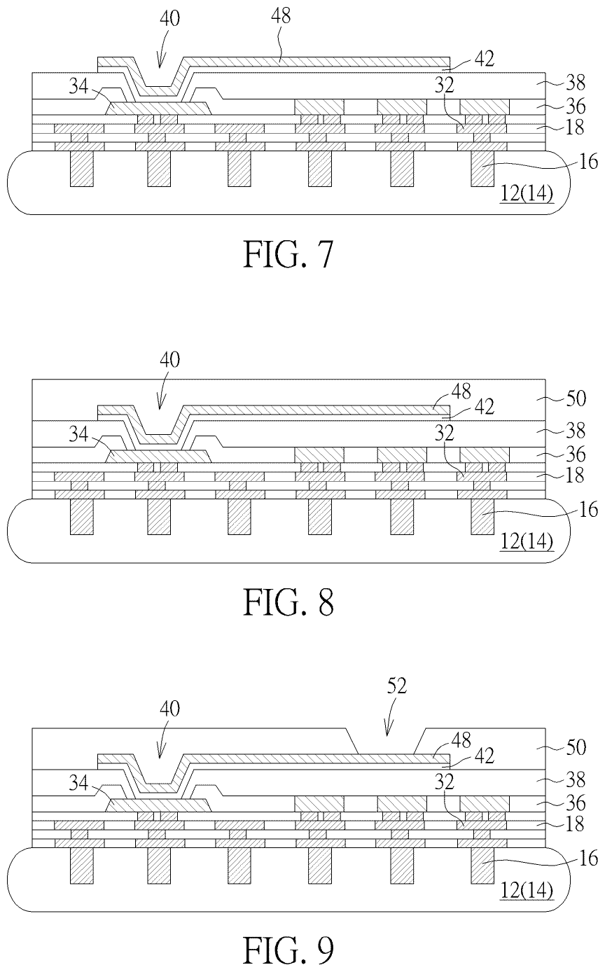

Next, as shown in FIG. 7, the first UBM layer 42 could be patterned by first removing the patterned mask 44 and then conducting an etching process by using the patterned metal layer 48 as mask to remove part of the first UBM layer 42 not covered by the metal layer 48 so that the edges or sidewalls of the patterned metal layer 48 are aligned with edges or sidewalls of the first UBM layer 42 underneath.

Next, as shown in FIG. 8, a second organic layer 50 is formed on the surface of the first organic layer 38 and the patterned metal layer 48, in which the first organic layer 38 and the second organic layer 50 could include same material or different materials. Similar to the first organic layer 38, the second organic layer 50 could include an organic dielectric layer made from organic material such as polyimide (PI), polybenzoxazole (PBO), or benzocyclobutene (BCB).

Next, as shown in FIG. 9, a photo-etching process conducted by using a patterned mask (not shown) such as patterned resist as mask to remove part of the second organic layer 50 for forming an opening 52 exposing part of the metal layer 48 underneath.

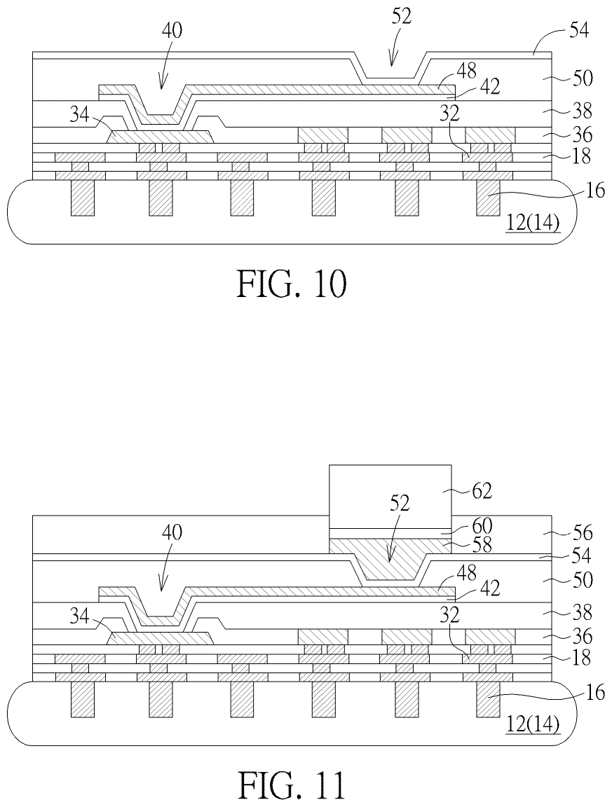

Next, as shown in FIG. 10, processes including sputtering, deposition, and etching could be carried out to form a second UBM layer 54 made of multiple UBM layers on the second organic layer 50 and the metal layer 48. Similar to the first UBM layer 42, the second UBM layer 54 could further include an adhesion layer, a barrier layer, and a wetting layer, in which the adhesion layer could include aluminum, titanium, chromium, titanium tungsten, or combination thereof, the barrier layer could include nickel or nickel vanadium, and the wetting layer could include copper, molybdenum, platinum, or combination thereof.

Next, as shown in FIG. 11, a patterned mask 56 such as patterned resist is formed on the second UBM layer 54, in which the patterned mask 56 includes an opening (not shown) exposing the second UBM layer 54 in the aforementioned opening 52. Next, an electroplating process is conducted to form a patterned metal layer 58, a patterned metal layer 60, and a solder 62 in the opening and on the surface of the second UBM layer 54. Preferably, the metal layer 58 includes copper (Cu), the metal layer 60 includes nickel (Ni), and the solder 62 includes tin (Sn), but not limited thereto.

Next, as shown in FIG. 12, after stripping the patterned resist 56, an etching process is conducted by using the solder 62 as mask to remove part of the second UBM layer 54 adjacent to two sides of the solder 62 and expose the surface of the second organic layer 50.

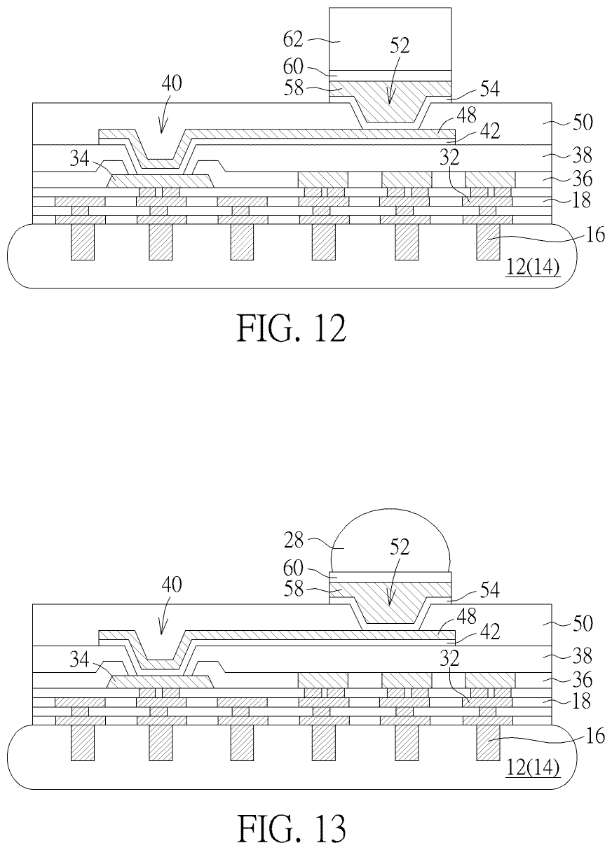

Next, as shown in FIG. 13, a reflow process is conducted transform the solder 62 through heat into a solder bump or micro bump 28 directly on top of each corresponding metal layers 58, 60. In this embodiment, the combination of the first organic layer 38 and second organic layer 50 is essentially the organic layer 20 shown in FIG. 1. Next, it would be desirable to bond dies 22, 24, 26 with different functionalities onto the organic layer 20 or second organic layer 50 through the micro bumps 28 as shown in FIG. 1, a molding layer 64 is formed around the dies 22, 24, 26, bottom of the substrate 14 is grinded to expose the TSVs 16, and then solder balls 30 are formed to connect to the TSVs 16. This completes the fabrication of a semiconductor device according to an embodiment of the present invention.

Overall, the present invention discloses an approach of integrating dies with different functionalities onto a wafer for forming a package structure, which first provides a silicon wafer or substrate 14 having elements fabricated through BEOL processes and TSVs 16 therein, forms an inorganic layer 18 on the substrate, forms an organic layer 20 on the inorganic layer, and then bonds dies 22, 24, 26 having different functionalities onto the organic layer 20 through micro bumps 28. According to a preferred embodiment of the present invention, by using transition of different material including inorganic layer and organic layer between silicon wafer and dies as a bonding medium, it would be desirable to boost up reliability and performance of the entire package structure significantly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
providing a substrate having through-silicon vias (TSVs) therein;
forming an inorganic layer on the substrate;
forming an organic layer on the inorganic layer; and
bonding dies having different functionalities on the organic layer.

2. The method of claim 1, wherein the inorganic layer comprises a metal interconnection therein.

3. The method of claim 2, further comprising:
forming a first organic layer on the inorganic layer;
patterning the first organic layer to form a first opening exposing the metal interconnection;
forming a first under bump metallurgy (UBM) layer in the first opening;
forming a second organic layer on the first UBM layer;
patterning the second organic layer to form a second opening exposing the first UBM layer;
forming a second UBM layer in the second opening; and
forming a micro bump on the second UBM layer.

4. The method of claim 3, further comprising patterning the first UBM layer before forming the second organic layer.

5. The method of claim 1, further comprising forming a molding layer around the dies.

6. The method of claim 1, wherein the dies comprise a radio-frequency integrated circuit (RFIC) die.

7. The method of claim 1, wherein the dies comprise a power amplifier (PA) die.

8. The method of claim 1, wherein the dies comprise a high electron mobility transistor (HEMT) die.

9. A semiconductor device, comprising:
a substrate having through-silicon vias (TSVs) therein;
an inorganic layer on the substrate;
an organic layer on the inorganic layer; and
dies having different functionalities bonded on the organic layer.

10. The semiconductor device of claim 9, wherein the inorganic layer comprises a metal interconnection therein.

11. The semiconductor device of claim 9, wherein the organic layer comprises:
a first organic layer on the inorganic layer; and
a second organic layer on the first organic layer.

12. The semiconductor device of claim 11, further comprising a first under bump metallurgy (UBM) layer on the first organic layer.

13. The semiconductor device of claim 11, further comprising a second UBM layer on the second organic layer.

14. The semiconductor device of claim 9, further comprising a molding layer around the dies.

15. The semiconductor device of claim 9, wherein the dies comprise a radio-frequency integrated circuit (RFIC) die.

16. The semiconductor device of claim 9, wherein the dies comprise a power amplifier (PA) die.

17. The semiconductor device of claim 9, wherein the dies comprise a high electron mobility transistor (HEMT) die.
